(19) United States
(12) Patent Application Publication
(10) Pub. No.: US 2024/0156261 A1
(43) Pub. Date: May 16, 2024

(54) POWER-SUPPLY DEVICE

(71) Applicant: Julius Blum GmbH, Hoechst (AT)

(72) Inventor: Dominik HAGSPIEL, Hoechst (AT)

(21) Appl. No.: 18/384,637

(22) Filed: Oct. 27, 2023

Related U.S. Application Data
(63) Continuation of application No. PCT/AT2022/060141, filed on Apr. 27, 2022.

(30) Foreign Application Priority Data
Apr. 30, 2021 (AT) A 50336/2021

(51) Int. Cl. A47B 88/919; H02B 1/04

(52) U.S. Cl. CPC A47B 88/919; H02B 1/04; A47B 2220/0075; A47B 2220/0091

(57) ABSTRACT

The invention relates to a power-supply device for an item of furniture that has a furniture carcass and at least one movable furniture part for supplying at least one electrical load with electrical power, the device comprising: at least one current-supply bar, wherein the current-supply bar can be arranged on the furniture carcass or on the movable furniture part; at least one contacting device, wherein the contacting device can be arranged at least in part on the movable furniture part or on the furniture carcass; wherein the contacting device comprises at least one contact element for galvanically conductively contacting the at least one current-supply bar, and at least one switchable load-switch element for allowing a current supply from the current-supply bar to the at least one electrical load via the contacting device.

The invention relates to an energy supply device with the features of the preamble of claim 1, a piece of furniture with such an energy supply device, a method for supplying an electrical consumer that can be arranged in or on such a piece of furniture with electrical energy by means of such an energy supply device, as well as the use of such an energy supply device for supplying at least one electrical consumer that can be arranged in or on such a piece of furniture with electrical energy.

Energy supply device for electrical consumers in or on pieces of furniture are known in the state of the art. A supply of an electrical consumer arranged in or on the piece of furniture—in particular a supply of a consumer arranged on or in a movable furniture part—with electrical energy can be produced or interrupted by a movement of the piece of furniture or of the movable furniture part. Due to a suddenly changing power input, the undesired formation of a spark gap can occur at a contacting device, which can contact a current supply rail of the piece of furniture. In the case of such a spark gap, an open arc can occur, which can result in damage to the electrical contacts of the contacting device and the current supply rail, as well as to disruption to the power supply and connected electrical consumers.

The object of the invention is to specify an energy supply device, a piece of furniture, a method for supplying enery, as well as a use of an energy supply device, in which the above-named disadvantages do not arise.

The object is achieved by an energy supply device with the features of claim 1, a piece of furniture with such an energy supply device, a method for supplying an electrical consumer that can be arranged in or on such a piece of furniture with electrical energy by means of such an energy supply device, as well as the use of such an energy supply device for supplying at least one electrical consumer that can be arranged in or on such a piece of furniture with electrical energy.

Advantageous embodiments of the invention are defined in the dependent claims.

The energy supply device is suitable for supplying at least one electrical consumer with electrical energy for a piece of furniture with a furniture carcass and at least one movable furniture part.

At least one electrical consumer can be arranged in or on the piece of furniture, in particular in or on the furniture carcass, and/or in or on the movable furniture part. It is not to be ruled out that the piece of furniture has several movable furniture parts and several electrical consumers.

The energy supply device can have at least one current supply rail, wherein the current supply rail can be arranged on the furniture carcass or on the movable furniture part. Electricity can be taken from the current supply rail to supply at least one electrical consumer.

The energy supply device can have at least one contacting device, wherein the contacting device can be arranged at least partially on the movable furniture part or on the furniture carcass.

The contacting device can have at least one contact element for galvanically conductively contacting the at least one current supply rail. Through the at least one contact element, the current supply rail can be contacted in a conductive manner.

The contacting device can further have at least one switchable load-switching element for enabling a current supply from the current supply rail to the at least one electrical consumer via the contacting device.

In principle, the energy supply device can have several contacting devices formed separately from each other. The energy supply device can also have several load-switching elements formed separately from each other.

The switchable load-switching element can essentially have an open switching state, in which no electricity can flow through the load-switching element, and a closed switching state, in which electricity can flow through the load-switching element.

The switchable load-switching element can, for example, be designed in the form of an electronic semiconductor component, such as for instance a bipolar transistor, a field-effect transistor, an optocoupler, a thyristor, a TRIAC or a semiconductor relay.

A formation of the switchable load-switching element by a remote-controlled switch in the form, for instance, of a relay, possibly with equipment for spark quenching, such as for instance a capacitor, a varistor or a suppressor diode, is not to be ruled out.

It can therefore be provided that a contacting device, which can contact the current supply rail in a galvanically conducting manner with at least one contact element and which can enable a current supply to the at least one electrical consumer with a switchable load-switching element, is arranged between the current supply rail and at least one electrical consumer.

In particular, it can be provided that the current supply rail is contactable by the contacting device via the contact element when the switchable load-switching element is in an open switching position.

When the at least one contact element of the contacting device is in contact with the current supply rail, the contacting device can be brought to the voltage potential of the current supply rail without a significant current flowing over the contact element.

Once the contacting device has successfully contacted the current supply rail, the switchable load-switching element can enable a current supply for the electrical consumer.

Conversely, the current supply for the electrical consumer can be disabled before the contact of the contact element of the contacting device is disengaged from the current supply rail.

In an advantageous embodiment, through a movement of the at least one movable furniture part relative to the furniture carcass, the at least one current supply rail can be galvanically conductively contactable by the at least one contact element and/or the at least one load-switching element can be switchable.

It is generally conceivable that a load-switching element enables a current supply for an electrical consumer in dependence on a further load-switching element.

The contact of the contact element with the current supply rail can be produced or interrupted by a movement of the movable furniture part. Alternatively or in the same way, the load-switching element can be switchable through a movement of the movable furniture part.

Through a movement into a predefined or predefinable position of the at least one movable furniture part relative to the furniture carcass, the at least one current supply rail can be galvanically conductively contactable by the at least one contact element and/or the at least one load-switching element can be switchable.

A predefined or predefinable position of the at least one movable furniture part relative to the furniture carcass can preferably be provided through a movement into or out of an end position of the movement of the at least one movable furniture part.

Thus, for example, a contacting of the current supply rail by the at least one contact element and/or a switching of the at least one load-switching element can be effected when the open position or closed position of a drawer or flap or door of a piece of furniture is reached or left.

The at least one load-switching element can have at least one measuring contact, wherein, with the at least one measuring contact, a galvanically conductive contacting of the contact element with the at least one current supply rail can be measurable. The at least one load-switching element can detect, via the at least one measuring contact, whether the measuring contact is contacting the current supply rail. In dependence on this, the load-switching element can have a predefined or predefinable switching positions.

The galvanically conductive contacting of the contact element with the at least one current supply rail can be measurable, using the measuring contact, through reaching a predefined or predefinable position of the at least one movable furniture part relative to the furniture carcass and/or by measuring a voltage applied to the at least one current supply rail.

A predefined or predefinable position of the at least one movable furniture part relative to the furniture carcass can preferably be provided through a movement into or out of an end position of the movement of the at least one movable furniture part.

Thus, for example, a contacting of the current supply rail by the at least one contact element can be detected and/or the application of a voltage to the contact element can be measured when the open position or closed position of a drawer or flap or door of a piece of furniture is reached or left. A detection of a contacting of the contact element on the current supply rail can essentially be effected in a position-dependent and/or voltage-dependent manner.

The at least one load-switching element can be able to enable a current supply from the current supply rail to the at least one electrical consumer in a substantially power-free manner. The load-switching element can enable a current supply from the current supply rail to the electrical consumer substantially without itself having a high power requirement. This can in particular be effected by a voltage-controlled switching of the load-switching element.

In an advantageous embodiment, the energy supply device can have at least one first load-switching element for a first electrical consumer and one second load-switching element for a second electrical consumer and the second load-switching element can be switchable in dependence on the switching state of the first load-switching element. For example, a contacting or an interruption of a contacting of the current supply rail for the first electrical consumer can be detected by the first load-switching element. The second load-switching element can be switchable depending on this.

The first load-switching element for the first electrical consumer and the second load-switching element for a second electrical consumer can be arranged
in or on the same piece of furniture
in or on the same furniture part
in or on different pieces of furniture
in or on different furniture parts.

In an advantageous embodiment, the at least one contact element and the at least one load-switching element can be arranged in a common modular unit.

The contact element can have a spring contact for galvanically conductively contacting the at least one current supply rail. A spring contact can, for example, permit a certain range of movement of a movable furniture part, within which a contacting of the current supply rail by the contact element remains in place.

The spring contact can have at least one pivotable spring finger.

With a pivotable spring finger of the spring contact, the at least one load-switching element can be switchable through a movement of the at least one pivotable spring finger. Thus, for example, the spring finger of the spring contact can come to rest against the current supply rail, as a result of which a galvanically conductive contact is produced. With continuing contact with the current supply rail, the pivotable spring finger can be pivoted and, for example, the measuring contact can be contacted, and the load-switching element switched.

The current supply rail can generally have at least two galvanically conductive contact surfaces or contact points. One of the contact surfaces or contact points can lie at a predefined or predefinable voltage potential compared to the other contact surface or contact point. Thus, for example, a supply voltage can be applied to one of the contact surfaces or contact points, whereas the other contact surface or contact point is connected to ground.

The energy supply device can generally comprise at least one direct current voltage source and/or at least one alternating current voltage source for supplying the at least one electrical consumer with electrical energy.

The energy supply device can have a rechargeable energy storage device from which, at least when the load switch of the energy supply device is open, an electrical consumer can be able to be supplied with electrical energy, at least for a limited duration.

As a result, an electrical consumer can be able to be supplied with electrical energy, at least for a limited duration, even without a contacting of the current supply rail.

The energy supply device can supply different consumers with electrical energy. For this, the energy supply device can have different interfaces for connecting electrical consumers and, if necessary, voltage regulators.

The electrical consumers can, for example, comprise radio transmitters, light sources, furniture drives, power supply units or plate warmers.

In an embodiment, for example when the movable furniture part is implemented as a drawer, an energy storage device of an electrical consumer can be recharged with the energy supply device when the drawer is closed.

Protection is also sought for a piece of furniture with a furniture carcass and at least one furniture part that is movable relative to the furniture carcass, in particular in the form of a drawer, wherein the at least one furniture part can be arranged at least partially in an interior of the furniture carcass, wherein the piece of furniture has at least one energy supply device as described above.

The movable furniture part can in particular be formed as a drawer, a furniture door or a furniture flap.

The contacting device can be arranged on a back wall, facing the interior of the furniture carcass, of the movable furniture part. For example, the contacting device can be arranged on a back wall of a drawer.

The current supply rail can be arranged on a back wall of the furniture carcass facing the interior of the furniture carcass. The current supply rail can extend along a vertical extension on the back wall of the furniture carcass facing the interior of the furniture carcass, for example.

In such an arrangement it can be provided, for example, that a contacting device arranged on a back wall of a drawer contacts a current supply rail arranged on the back wall of the furniture carcass when the drawer is closed, or a contact is disengaged when the drawer is opened.

The at least one movable furniture part can have at least one interface to which at least one electrical consumer can be detachably coupled. For example, such an interface can be in the form of a plug connection, a USB bus system or an interface for wireless energy transfer.

In an embodiment, the piece of furniture can have at least one electrical consumer. Such an electrical consumer can be provided, for example, by a radio transmitter, a lighting device, a furniture drive or a plate and cup warmer. A lighting device can be arranged in or on the furniture carcass and in or on a movable furniture part.

In an embodiment, at least one electrical consumer in the form of at least one light source can be arranged in or on the furniture carcass and the at least one light source can be arranged above the at least one movable furniture part, based on the installed position. When a first and second load-switching element as described above is present, the light source can be switched on or off, for example with a movement of the movable furniture part.

Protection is also sought for a method for supplying an electrical consumer that can be arranged in or on a piece of furniture with electrical energy by means of an energy supply device as described above for a piece of furniture as described above.

In a contacting method step, a contacting device can galvanically conductively contact at least one current supply rail with at least one contact element.

In a enabling method step, with at least one load-switching element, a current supply from the current supply rail to the at least one electrical consumer can be enabled via the contacting device.

Advantageously, when a predefined or predefinable position of the at least one movable furniture part relative to the furniture carcass is reached during a movement of the at least one movable furniture part towards the furniture carcass, at least one current supply rail can be galvanically conductively contacted the at least one contact element. Subsequently, for example continued movement or an electronic or mechanical circuit, the at least one load-switching element can enable a current supply from the current supply rail to the at least one electrical consumer via the contacting device.

It is conceivable that a load-switching element of the energy supply device enables a current supply from the current supply rail to at least one electrical consumer via the contacting device by switching another load-switching element.

In an advantageous embodiment, in a contact-measuring method step, a galvanically conductive contacting of the contact element with the at least one current supply rail can be measured with at least one measuring contact of the at least one load-switching element.

In an advantageous embodiment, the galvanically conductive contacting of the contact element with the at least one current supply rail can be measurable, using the measuring contact, through reaching a predefined or predefinable position of the at least one movable furniture part relative to the furniture carcass and/or by measuring a voltage applied to the at least one current supply rail.

The measuring contact can detect a position of the movable furniture part relative to the furniture carcass and/or measure the application of a voltage to the contact element.

A predefined or predefinable position of the at least one movable furniture part relative to the furniture carcass can preferably be provided through a movement into or out of an end position of the movement of the at least one movable furniture part.

In an advantageous embodiment, the energy supply device can have at least one first load-switching element for a first electrical consumer and one second load-switching element for a second electrical consumer and a switching of the second load-switching element can be effected in dependence on the switching state of the first load-switching element.

For example, a contacting or an interruption of a contacting of the current supply rail for the first electrical consumer can be detected by the first load-switching element in a contact-measuring method step. The second load-switching element can be switched in a enabling method step depending on this.

Protection is also sought for a use of an energy supply device as described above for supplying at least one electrical consumer that can be arranged in or on a piece of furniture with electrical energy.

Embodiment examples of the invention are discussed with reference to the figures. There are shown in:

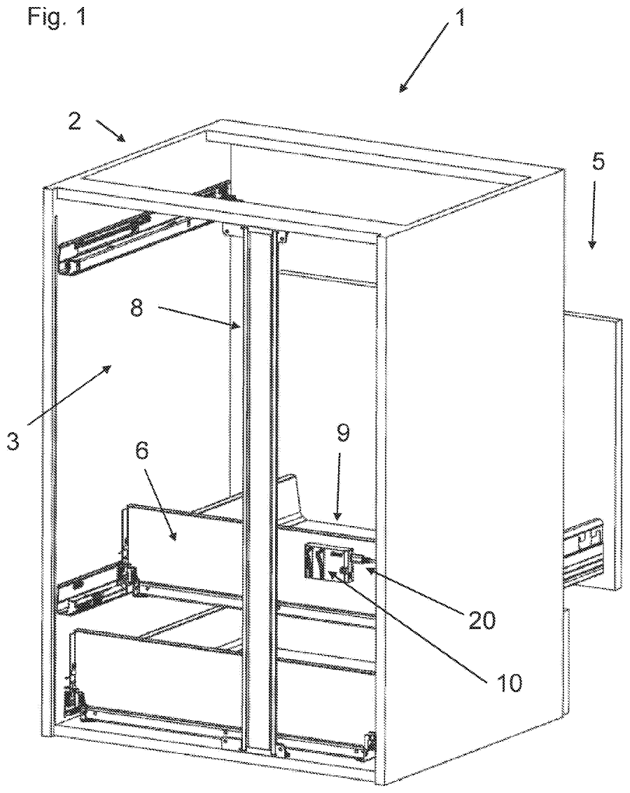

FIG. 1 a perspective back view of an embodiment of a piece of furniture,

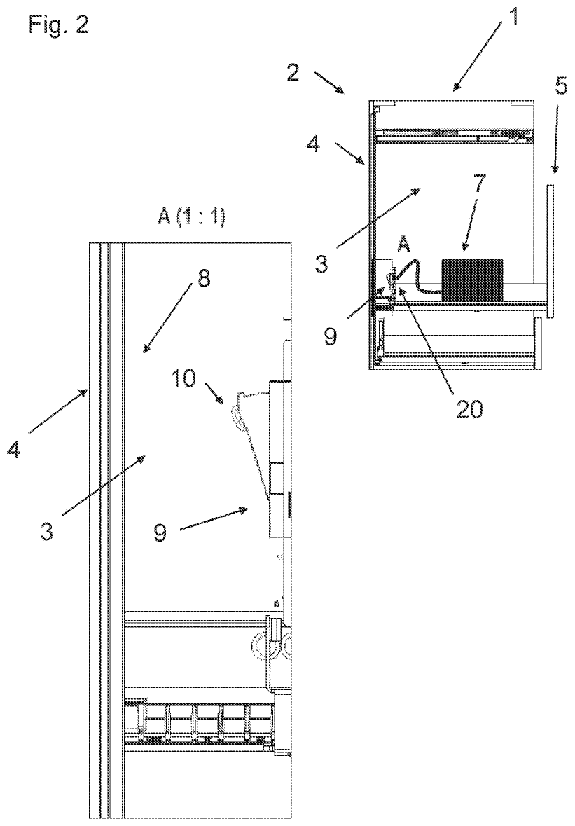

FIG. 2 side views of a sectional representation and a detailed view for FIG. 1,

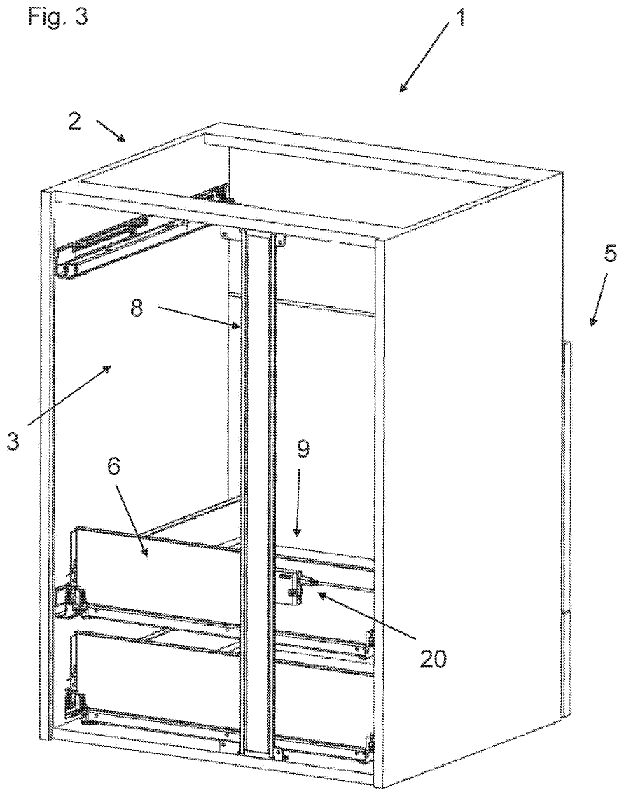

FIG. 3 a further perspective back view of an embodiment of a piece of furniture,

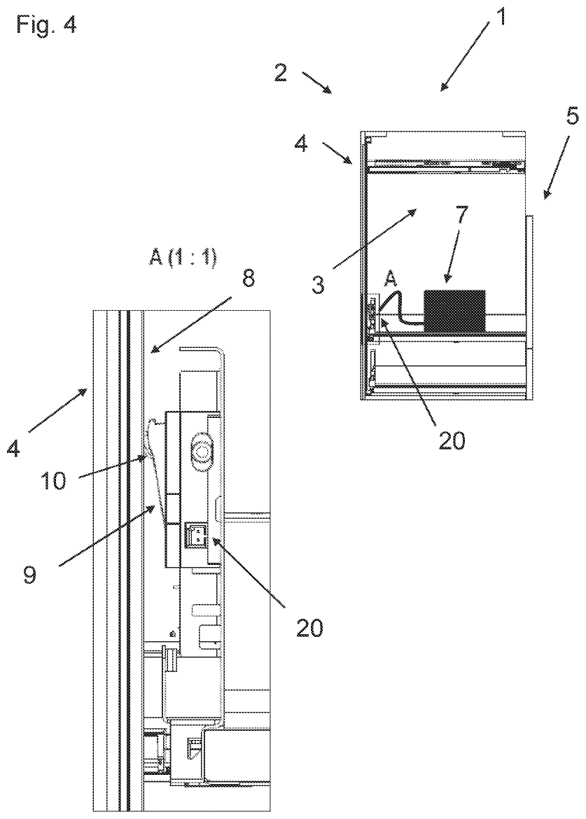

FIG. 4 side views of a sectional representation and a detailed view for FIG. 3,

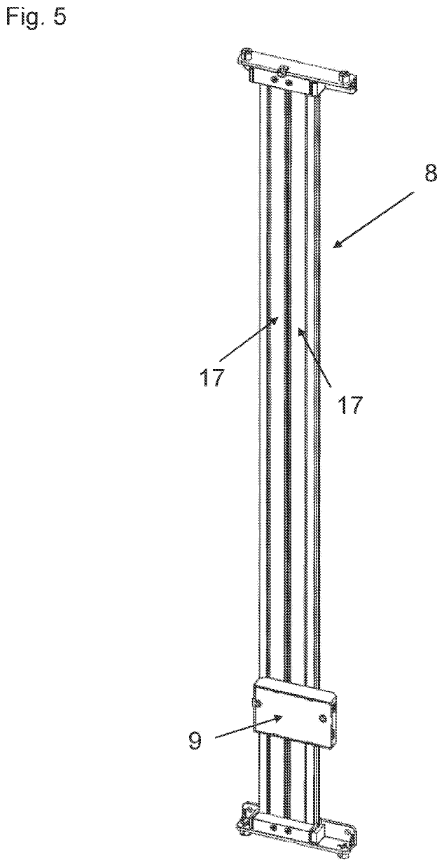

FIG. 5 a detailed representation of an embodiment of the contacting device and the current supply rail,

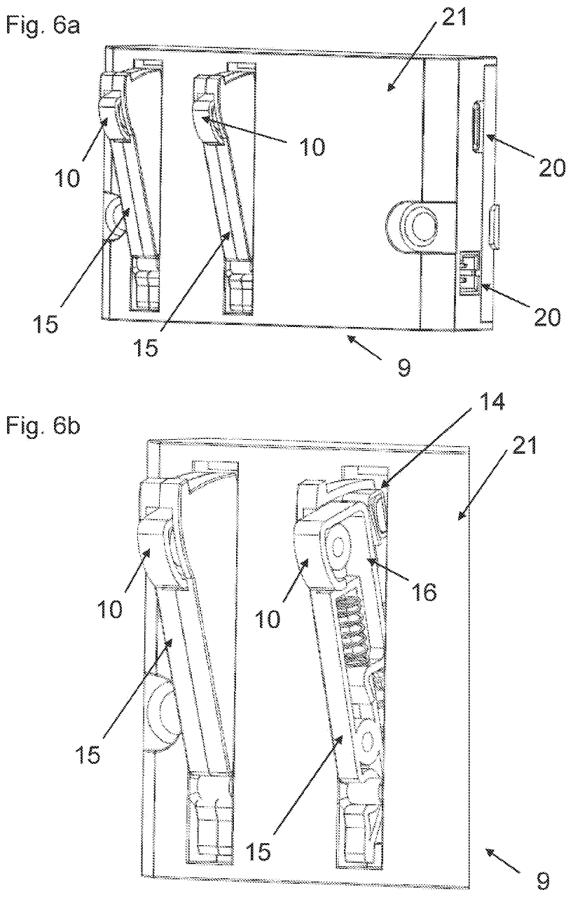

FIGS. 6a and 6b detailed views of an embodiment of the contacting device,

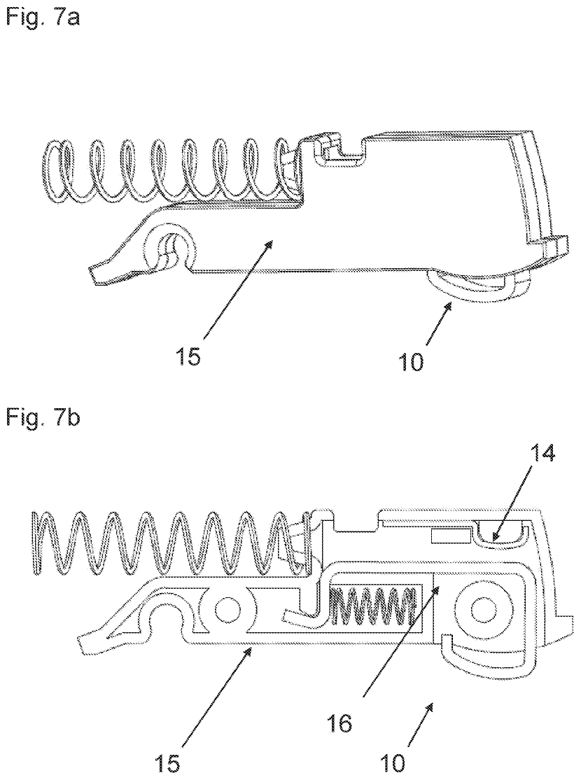

FIGS. 7a and 7b detailed views of an embodiment of a spring contact,

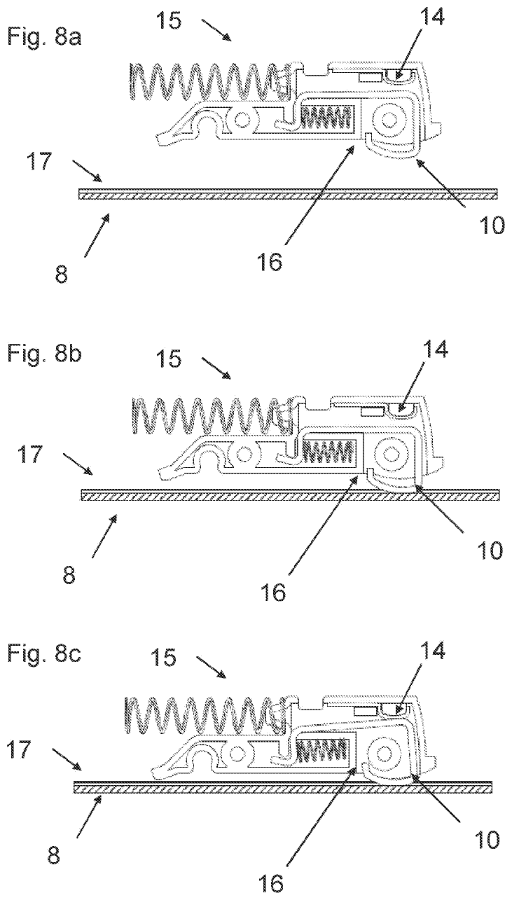

FIGS. 8a to 8c detailed views of a contacting of a current supply rail with a spring contact,

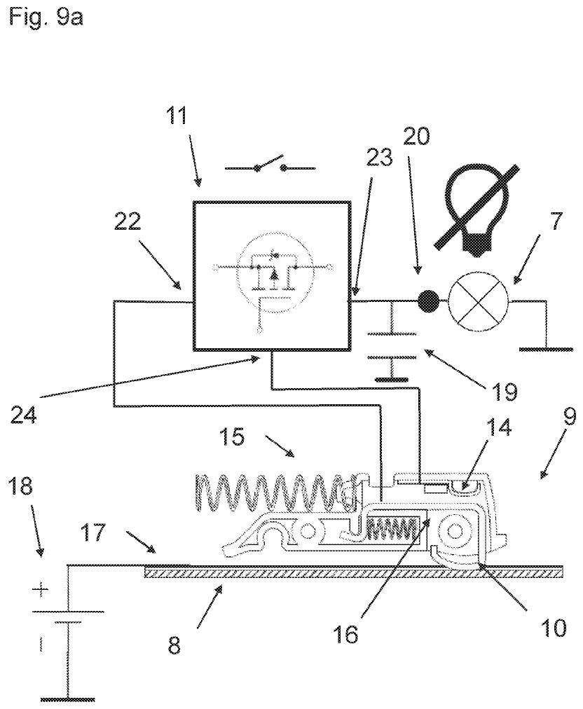

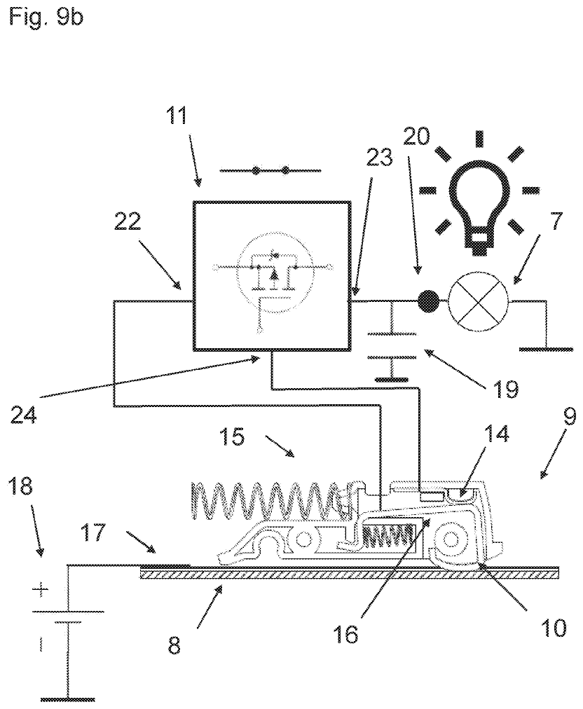

FIGS. 9a and 9b schematic circuit diagrams for the use of an embodiment of an energy transfer device, and

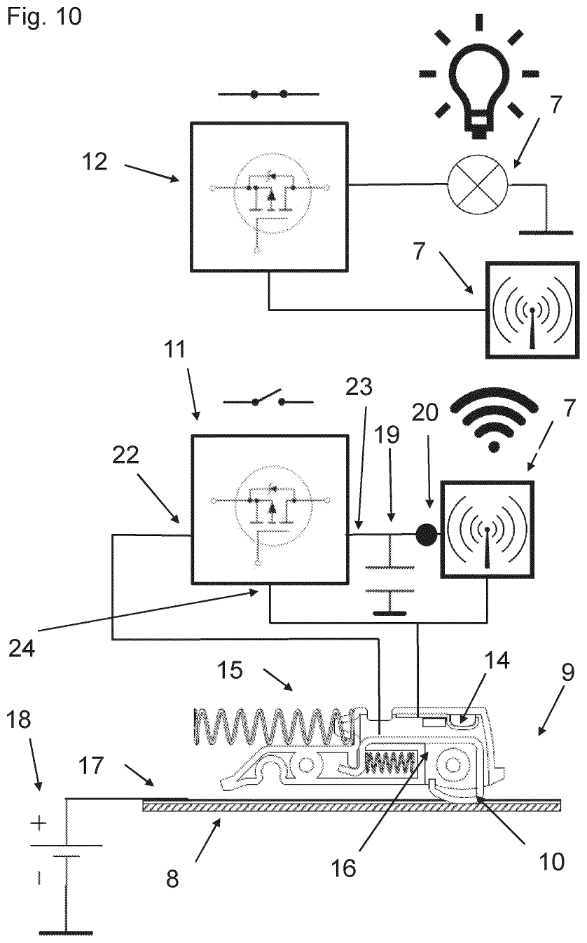

FIG. 10 a schematic representation of the switching of a load-switching element in dependence on another load-switching element.

FIG. 1 shows a perspective back view of an embodiment of a piece of furniture 1 with a furniture carcass 2 and a movable furniture part 5 in the form of a drawer partially arranged in the interior 3 of the furniture carcass. In the embodiment shown, the piece of furniture 1 has a current supply rail 8 running along a vertical extension of the furniture carcass 2 on the back side. A contacting device 9 with contact element 10 is arranged on a back wall 6 of the movable furniture part 5.

In FIG. 2, side views of a sectional representation and a detailed view of the piece of furniture 1 shown in FIG. 1 are represented. It is to be identified here that the movable furniture part 5 in the form of the drawer is partially arranged in the interior 3 of the furniture carcass 2. An electrical consumer 7 connected to the contacting device 9 via an interface 20 is arranged in the movable furniture part 5 in the form of drawer. As can be seen from the detailed view in detail A, the contacting device 9 with the contact elements 10 is spaced apart from the current supply rail 8 attached to the back wall 4 of the furniture carcass 2, there is thus no galvanically conducting connection of the contact elements 10 to the current supply rail 8.

FIG. 3 shows a perspective back view of the embodiment of a piece of furniture 1 according to FIG. 1, wherein the movable furniture part 5 in the form of a drawer arranged in the interior 3 of the furniture carcass has been brought into an end position of the movement corresponding to the closed position of the furniture part 5 relative to the furniture carcass 2.

As can be seen from the side views of the sectional representations of FIG. 4, here the contacting device 9 has come into contact with the current supply rail 8 with the contact elements 10, as a result of which a galvanically conducting connection of the contact elements 10 with the current supply rail 8 has formed.

FIG. 5 shows a detailed representation of the contacting device 9 and the current supply rail 8, which has 2 contact surfaces 17 in the embodiment shown, wherein the direction of view is directed out of the interior 3 in the direction of the back wall 4 with reference to FIG. 4.

A detailed view of an embodiment of the contacting device 9 is shown in FIGS. 6a and 6b. The contacting device 9 has two spring contacts 15 that are pivotably mounted on a housing 21 and on each of which a contact element 10 for contacting the contact surfaces 17 of the current supply rail 8 is arranged.

The spring contacts 15 can, for example, permit a certain range of movement of the movable furniture part 5, within which a contacting of the current supply rail 8 by the contact element 10 remains in place.

As can be seen from the sectional representation of FIG. 6b and can also be seen from FIGS. 7a and 7b and FIGS. 8a to 8c, the spring contacts 15 have spring fingers 16 mounted pivotably on the spring contacts 15.

The spring contacts 15 and the spring fingers 16 can each have energy storage mechanisms, for example in the form of a spring, for resetting the pivoting movement.

In the embodiment shown, the spring contact 15 of the contacting device 9 also contains the measuring contact 14.

If the contacting device 9 is arranged on the movable furniture part 5, when the furniture part 5 is moved relative to the furniture carcass 2, the contacting device 9 can approach the contact surfaces 17 of the current supply rail 8 with the contact elements 10.

As is represented in a transition of FIG. 8a to 8b—for example in a contacting method step—the contacting device 9 can thereby galvanically conductively contact the at least one current supply rail 8 with at least one contact element 10.

In the case of a continuation of the relative movement, as represented in a transition of FIG. 8b to 8c—for example in a contact-measuring method step—a galvanically conductive contacting of the contact element 10, which is again in galvanically conductive contact with the at least one current supply rail 8, can be effected the measuring contact 14. In an alternative embodiment, the measuring contact 14 can, for example, be arranged spatially offset with respect to the contact element 10 such that a contacting of the current supply rail by the measuring contact 14 is effected after a contacting of the contact element 10 with the current supply rail 8.

A circuit diagram for the use of an embodiment of an energy transfer device of a piece of furniture 1 is represented schematically in FIGS. 9a and 9b.

In FIG. 9a, a contact surface 17 of a current supply rail 8 is contacted by a voltage source 18 in the form of a direct current voltage source. A contact element 10 of a spring contact 15 of a contacting device 9 (not represented in more detail here) is in a galvanically conductive connection with the current supply rail 8.

In the embodiment shown, the load-switching element 11 is implemented by way of example with a field-effect transistor as switching element, wherein the switching state of the load-switching element 11 is represented symbolically by an open and a closed switch.

In the embodiment shown, the energy supply device also has an energy storage device 19 in the form of a capacitor. The energy storage device 19 can supply an electrical consumer 7 with energy irrespective of the switching position of the load-switching element 11, at least for a limited duration.

The contact element 10 in the form of the pivotable spring finger 16 is connected to an input 23 of a switchable load-switching element 11. The measuring contact 14 is connected to a control input 24 of the switchable load-switching element 11. An electrical consumer 7, here implemented schematically and by way of example by a light source, is connected to an output 23 of the switchable load-switching element 11.

In the embodiment shown, the load-switching element 11 is formed to measure, using the measuring contact 14, the galvanically conductive contacting of the contact element 10 with the at least one current supply rail 8 by measuring a voltage applied to the at least one current supply rail 8. When a voltage is applied to the control input 24 of the switchable load-switching element 11, the load-switching element 11 can—for example in a enabling method step—be enabled a current supply from the current supply rail 8 to the at least one electrical consumer 7 via the contacting device 9.

Once the spring finger 16 of the spring contact 15 has come to rest against the current supply rail 8, the pivotable spring finger 16 can be pivoted, with continuing contact with the current supply rail 8, as in the transition from FIG. 9a to FIG. 9b, and in the process the measuring contact 14 can contact the already live spring finger 16, as a result of which the load-switching element 11 can be switched and the electrical consumer 7 can be supplied with electrical energy.

In the reverse order of FIGS. 8 and 9, a regulated disconnection of the supply of an electrical consumer 7 with electrical energy can be effected.

Contrary to what is represented, the measuring contact 14 can also be implemented in the form of a position-dependent switch, which switches the load-switching element 11 once the contacting device 9 has contacted the current supply rail 8.

In FIG. 10, the electrical consumer 7 is designed in the form of a radio transmitter, which can broadcast a radio signal in dependence on the switching position of the load-switching element 11. As represented, after the energy supply of the electrical consumer 7, in the form of the radio transmitter, by the current supply rail 8 has been interrupted it can be supplied with electrical energy by the energy storage device 19, at least for a limited duration. An interruption of the current supply by the current supply rail 8 can be detected by the electrical consumer 7 itself or by communication with the load-switching element 11 switched into an open position. Such an interruption can be effected, for example, by a movement of the movable furniture part 5, for example when a drawer is opened.

The radio signal can be received by a further electrical consumer 7 in the form of a radio receiver, which switches the further load-switching element 12, as represented, into a closed switching position for example, in which an electrical consumer 7 in the form of a lighting device for example can be supplied with electrical energy. The electrical consumer 7 in the form of the radio receiver can be supplied with electrical energy irrespective of the switching position of the further load-switching element 12.

### LIST OF REFERENCE NUMBERS

1 piece of furniture
2 furniture carcass
3 interior
4 furniture carcass back wall
5 furniture part
6 furniture part back wall
7 electrical consumer
8 current supply rail
9 contacting device
10 contact element
11 load-switching element
12 load-switching element
13 electrical consumer
14 measuring contact
15 spring contact
16 spring finger
17 contact surfaces
18 voltage source
19 energy storage device
20 interface
21 housing
22 input
23 output
24 control input

1. An energy supply device for a piece of furniture with a furniture carcass and a movable furniture part for supplying an electrical consumer with electrical energy, the energy supply device comprising:
a current supply rail, wherein the current supply rail can be arranged on the furniture carcass or on the movable furniture part; and
a contacting device to be arranged at least partially on the movable furniture part or on the furniture carcass, the contacting device including:
a contact element for galvanically conductively contacting the current supply rail; and
a switchable load-switching element for enabling a current supply from the current supply rail to the electrical consumer via the contacting device.

2. The energy supply device according to claim 1, wherein, through a movement of the movable furniture part relative to the furniture carcass, the current supply rail is galvanically conductively contactable by the contact element and/or the load-switching element is switchable.

3. The energy supply device according to claim 2, wherein, through a movement into a predefined or predefinable position of the movable furniture part relative to the furniture carcass, preferably through a movement into or out of an end position of the movement of the movable furniture part, the current supply rail is galvanically conductively contactable by the contact element and/or the load-switching element is switchable.

4. The energy supply device according to claim 1, wherein the load-switching element has measuring contact and, with the measuring contact, a galvanically conductive contacting of the contact element with the current supply rail is measurable.

5. The energy supply device according to claim 4, wherein the galvanically conductive contacting of the contact element with the current supply rail is measurable, using the measuring contact, through reaching a predefined or predefinable position of the movable furniture part relative to the furniture carcass and/or by measuring a voltage applied to the current supply rail.

6. The energy supply device according to claim 1, wherein a current supply from the current supply rail to the electrical consumer can be enabled in a substantially power-free manner by the load-switching element.

7. The energy supply device according to claim 1, wherein the energy supply device has at least ene load-switching element is a first load-switching element for a first electrical consumer, the energy supply device further comprising and a second load-switching element for a second electrical consumer, and the second load-switching element is switchable depending on the switching state of the first load-switching element.

8. The energy supply device according to claim 1, wherein the contact element and the load-switching element are arranged in a common modular unit.

9. The energy supply device according to claim 1, wherein the contact element has a spring contact for galvanically conductively contacting the current supply rail.

10. The energy supply device according to claim 9, wherein the spring contact has a pivotable spring finger.

11. The energy supply device according to claim 10, wherein the load-switching element is switchable by a movement of the pivotable spring finger.

12. The energy supply device according to claim 1, wherein the current supply rail has at least two galvanically conductive contact surfaces or contact points.

13. The energy supply device according to claim 1, wherein the energy supply device comprises a voltage source, in particular a direct current voltage source and/or an alternating current voltage source, for supplying the electrical consumer with electrical energy.

14. The energy supply device according to claim 1, we further comprising a rechargeable energy storage device, from which, at least when the load-switching element is open, the electrical consumer is to be supplied with electrical energy, at least for a limited duration.

15. A piece of furniture comprising a furniture carcass, a furniture part movable relative to the furniture carcass, in particular in the form of a drawer, wherein the furniture part is to be arranged at least partially in an interior of the furniture carcass, and the energy supply device according to claim 1.

16. The piece of furniture according to claim 15, wherein the contacting device of the energy supply device is arranged on a back wall, facing an interior of the furniture carcass, of the movable furniture part.

17. The piece of furniture according to claim 15, wherein the current supply rail of the energy supply device is arranged on a back wall of the furniture carcass facing an interior of the furniture carcass.

18. The piece of furniture according to claim 15, wherein the movable furniture part has an interface preferably formed on the contacting device to which the electrical consumer is to be detachably coupled.

19. The piece of furniture according to claim 15, further comprising an electrical consumer.

20. The piece of furniture according to claim 15, wherein further comprising an electrical consumer in the form of a light source i-s-arranged in or on the furniture carcass, and the light source is arranged above the movable furniture part, based on an installed position.

21. A method for supplying an electrical consumer that can be arranged in or on a piece of furniture with electrical energy by the energy supply device according to claim 1 one a piece of furniture, the method comprising:
galvanically conductively contacting the current supply rail with the contact element using a contacting device; and
enabling a current supply from the current supply rail to the electrical consumer via the contacting device and the load-switching element.

22. The method according to claim 21, wherein, when a predefined or predefinable position of the movable furniture part relative to the furniture carcass is reached during a movement of the movable furniture part towards the furniture carcass, the contact element galvanically conductively contacts the current supply rail, and subsequently the load-switching element enables a current supply from the current supply rail to the electrical consumer via the contacting device.

23. The method according to claim 21, wherein, in a contact-measuring method step, a galvanically conductive contacting of the contact element with the current supply rail is measured with a measuring contact of the load-switching element.

24. The method according to claim 21, wherein the galvanically conductive contacting of the contact element with the current supply rail is measurable, using the measuring contact, through reaching a predefined or predefinable position of the movable furniture part relative to the furniture carcass and/or by measuring a voltage applied to the current supply rail.

25. The method according to claim 21, wherein the load-switching element is a first load-switching element for a first electrical consumer, and the energy supply device further comprising a second load-switching element for a second electrical consumer, and a switching of the second load-switching element is effected depending on a switching state of the first load-switching element.

26. A use of the energy supply device according to claim 1 for supplying the electrical consumer to be arranged in or on a piece of furniture with electrical energy.
